(19) United States
(12) Patent Application Publication
(10) Pub. No.: US 2011/0089544 A1
(43) Pub. Date: Apr. 21, 2011

(54) PACKAGE, MANUFACTURING METHOD THEREOF, AND SEMICONDUCTOR DEVICE

(75) Inventor: Koji Ono, Sagamihara-shi (JP)

(73) Assignee: CANON KABUSHIKI KAISHA, Tokyo (JP)

(21) Appl. No.: 12/893,103

(22) Filed: Sep. 29, 2010

(30) Foreign Application Priority Data
Oct. 21, 2009 (JP) 2009-242784

(51) Int. Cl. H01L 23/495; H01L 21/02

(52) U.S. Cl. 257/666; 438/123; 257/E23.031; 257/E21.002

(57) ABSTRACT

A package for mounting a semiconductor chip is provided. The package includes a frame member including an aperture, a first lead including a portion connectable to the semiconductor chip and a portion projecting outside from an outer sidewall of the frame member, and a second lead including a portion connectable to the semiconductor chip and a portion projecting inside the aperture from an inner sidewall of the frame member.

### BACKGROUND OF THE INVENTION

1. Field of the Invention

The present invention relates to a package for mounting a semiconductor chip, a manufacturing method of the package, and a semiconductor device.

2. Description of the Related Art

A plastic package formed using a lead frame to mount a semiconductor chip is widely used in a semiconductor device. In recent years, the number of input/output signal wires has increased as a result of digitalization of output electrical signals. Accordingly, the number of input/output terminals of the package also needs to be increased. Miniaturization of the package is also required along with the miniaturization of a device on which a semiconductor device is mounted. In general, the input/output terminals are formed along the outer periphery of the package formed using a lead frame. Therefore, the outer periphery of the package needs to be elongated to increase the number of input/output terminals. As a result, the package is also enlarged. To solve the problem, Japanese Patent Laid-Open No. 2002-246532 proposes an LGA (Land Grid Array) type package. In the LGA type package, the lead frame is pressed and formed into a wave shape, and resin molding is performed after cutting the upper side of the wave shape. In this way, input/output terminals are formed on the backside of the package.

However, a land-shaped terminal, such as the LGA type, is soldered only on the lower side of the input/output terminals. Therefore, the reliability of a solder joint may decrease depending on an application or the type of a mounting board. An aspect of the present invention provides a technique for realizing an increase in the number of terminals and an improvement in reliability of the solder joint.

### SUMMARY OF THE INVENTION

According to one aspect of the present invention, a package for mounting a semiconductor chip is provided. The package includes a frame member including an aperture, a first lead including a portion connectable to the semiconductor chip and a portion projecting outside from an outer sidewall of the frame member, and a second lead including a portion connectable to the semiconductor chip and a portion projecting inside the aperture from an inner sidewall of the frame member.

Further features of the present invention will become apparent from the following description of exemplary embodiments (with reference to the attached drawings).

### BRIEF DESCRIPTION OF THE DRAWINGS

The accompanying drawings, which are incorporated in and constitute a part of the specification, illustrate embodiments of the invention, and together with the description, serve to explain the principles of the invention.

FIGS. 1A and 1B are diagrams for explaining an exemplary package 100 of an embodiment;

FIGS. 2A and 2B are diagrams for explaining an exemplary solid-state image sensor 200 of an embodiment;

FIGS. 3A to 3D are diagrams for explaining an exemplary manufacturing method of the package 100 of an embodiment;

FIG. 4 is a diagram for explaining an exemplary package 400 of another embodiment;

FIG. 5 is a diagram for explaining an exemplary solid-state image sensor 500 of another embodiment;

FIG. 6 is a diagram for explaining an exemplary package 600 of another embodiment; and

FIG. 7 is a diagram for explaining an exemplary solid-state image sensor 700 of another embodiment.

### DESCRIPTION OF THE EMBODIMENTS

Embodiments of the present invention will now be described with reference to the attached drawings.

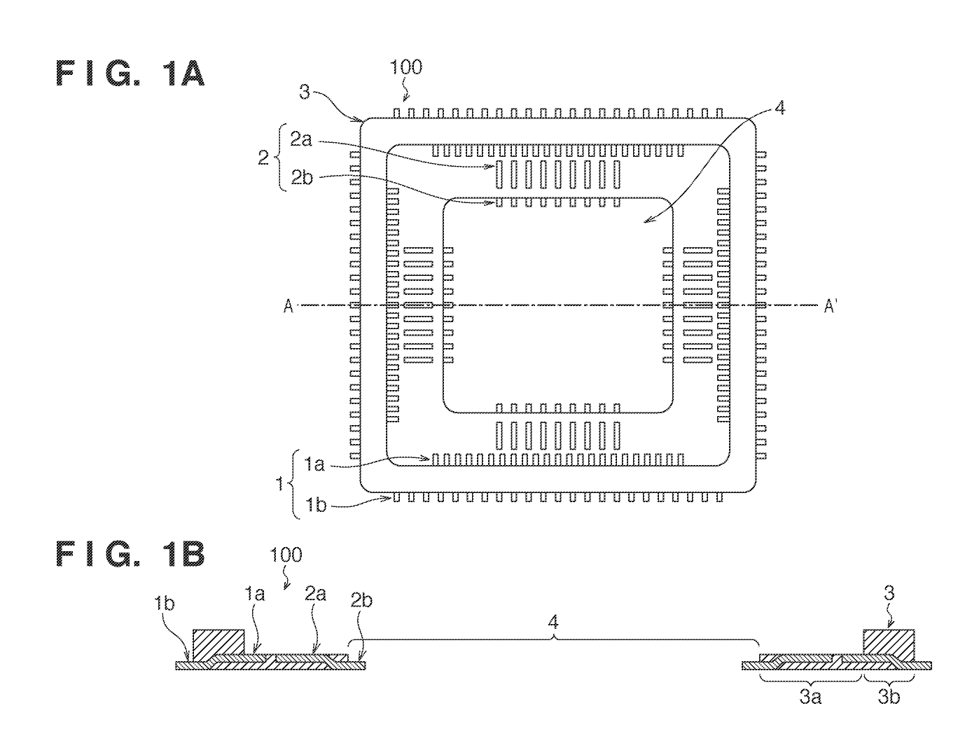

An exemplary package 100 of an embodiment will now be described with reference to FIGS. 1A and 1B. FIG. 1A shows a plan view of the package 100, and FIG. 1B shows an A-A′ cross-sectional view of the package 100. The package 100 comprises first leads 1, second leads 2, and a frame member 3. The frame member 3 of the present embodiment comprises inner peripheral portions 3a and outer peripheral portions 3b adjacent to each other. The height of the outer peripheral portions 3b is higher than the height of the inner peripheral portions 3a, and the frame member 3 has a concave shape. The frame member 3 is formed by, for example, a resin. The frame member 3 comprises an aperture 4 at the inner peripheral portions 3a, and the aperture 4 forms a hole in a vertical direction in the frame member 3. In the present specification, the side that a semiconductor chip is mounted on will be referred to as an upper direction, and the side of a board will be referred to as a lower direction. In the frame member 3, a plurality of first leads 1 are formed in the outer peripheral portions, and a plurality of second leads 2 are formed in the inner peripheral portions.

The first leads 1 comprise exposed portions 1a used for connection to the semiconductor chip mounted on the package 100 and protrusive portions 1b used for connection to the mounting board. The exposed portions 1a are exposed at the upper side of the frame member 3, and the semiconductor chip is electrically connected to the exposed portions 1a. The protrusive portions 1b project outside from outer sidewalls. The protrusive portions 1b are used to solder the first leads 1 to the mounting board.

The second leads 2 comprise exposed portions 2a used for connection to the semiconductor chip mounted on the package 100 and protrusive portions 2b used for connection to the mounting board. The exposed portions 2a are exposed at the upper side of the frame member 3, and the semiconductor chip is electrically connected to the exposed portions 2a. The protrusive portions 2b project inside the aperture 4 from inner sidewalls of the frame member 3. The protrusive portions 2b are used to solder the second leads 2 to the mounting board. The package 100 includes the second leads 2 in the present embodiment. Therefore, the number of terminals can be increased without enlarging the size of the package 100.

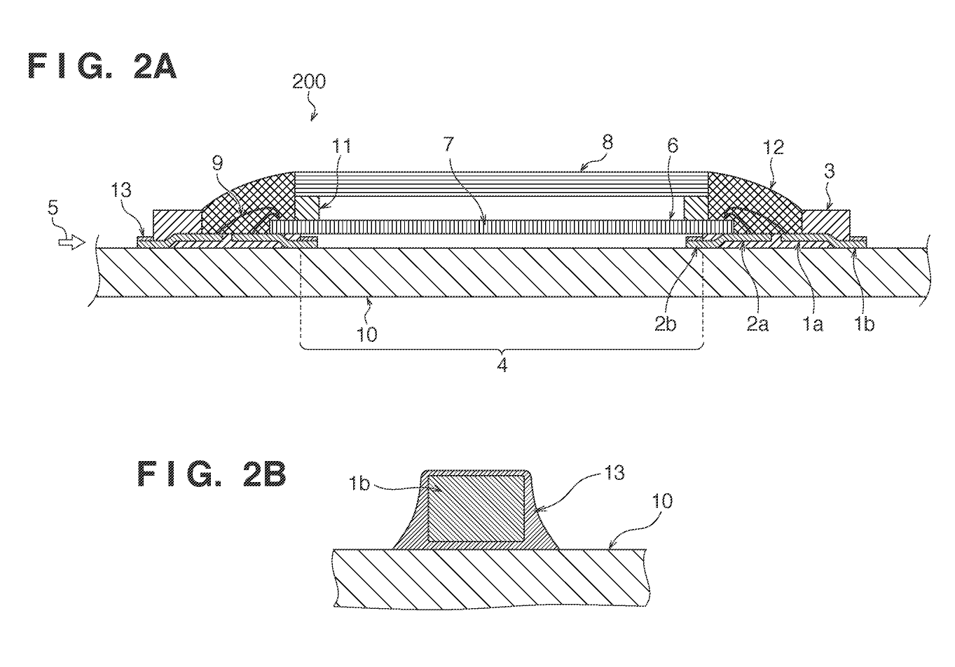

An exemplary semiconductor device including a semiconductor chip mounted on the package 100 will now be described with reference to FIGS. 2A and 2B. The present embodiment illustrates an example of a solid-state image sensor 200 using a solid-state image sensing element chip 6 as a semiconductor chip. However, the present invention can be applied to any semiconductor chip electrically connectable to the package 100. FIG. 2A is a cross-sectional view of the solid-state image sensor 200 mounted on a mounting board 10. FIG. 2B is a partial cross-sectional view of the protrusive portion 1b as seen from a direction of an arrow 5.

The solid-state image sensing element chip 6 is mounted on the package 100 so as to cover the aperture 4. In the present embodiment, the aperture 4 is smaller than the solid-state image sensing element chip 6 so that the solid-state image sensing element chip 6 completely covers the aperture 4. However, the solid-state image sensing element chip 6 may be smaller than the aperture 4, and the solid-state image sensing element chip 6 may cover part of the aperture 4. The smaller the aperture 4 compared to the solid-state image sensing element chip 6, the wider the bonded region when the solid-state image sensing element chip 6 is mounted on the package 100, and bonding is facilitated. On the other hand, if the aperture 4 is greater, interference between the second leads 2 can be prevented, and the number of second leads 2 can be increased. Therefore, the size of the aperture 4 is selected according to the number of required input/output terminals. For example, the size of the aperture 4 can be about 50 to 90% of the size of the solid-state image sensing element chip 6.

The solid-state image sensing element chip 6 is electrically connected to the exposed portions 1a and 2a by a bonding wire 9, which is a thin metallic wire, made of gold, aluminum, etc. A sealing frame 11 is bonded on the solid-state image sensing element chip 6 so as to surround a light-receiving region 7. A transparent member 8 made of glass, crystal, etc. is bonded on the sealing frame 11 to hermetically seal the light-receiving region 7. A sealing resin 12 is coated on the bonding wire 9 and outer peripheral portions of the solid-state image sensing element chip 6.

The protrusive portions 1b and 2b are soldered to the mounting board 10 by a solder 13. As shown in FIG. 2B, the solder 13 is wet and spread throughout the entire circumstance of the protrusive portion 1b. The solder 13 is also wet and spread around the protrusive portion 2b. Therefore, the package 100 of the present embodiment realizes highly reliable solder joints. Furthermore, in the solid-state image sensor 200 of the present embodiment, the backside of the solid-state image sensing element chip 6 is exposed, and a space is formed between the solid-state image sensing element chip 6 and the mounting board 10. Therefore, a heat radiating component can be installed in the space. Furthermore, the solid-state image sensing element chip 6 can directly radiate heat, and the heat radiation performance can be improved as compared to a conventional LGA type semiconductor device.

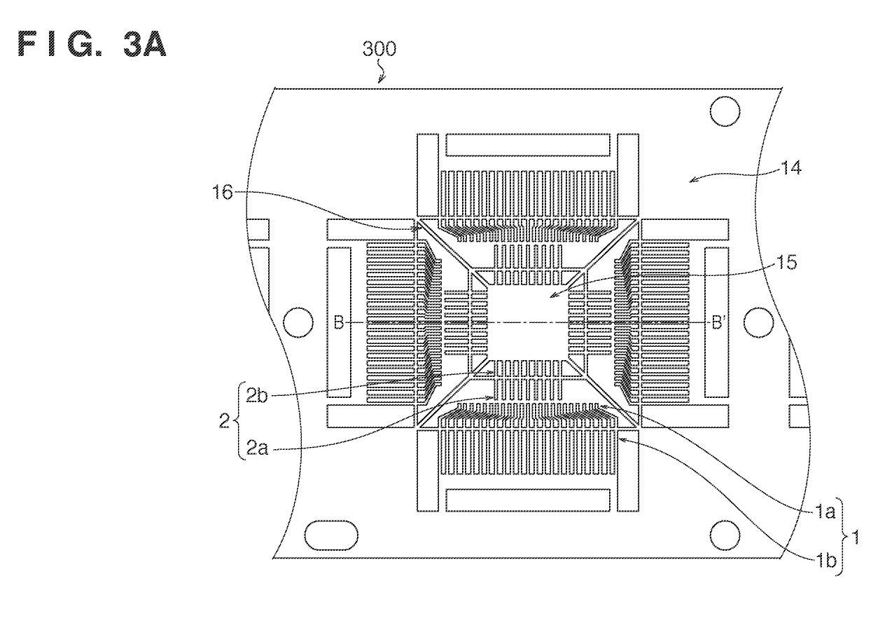

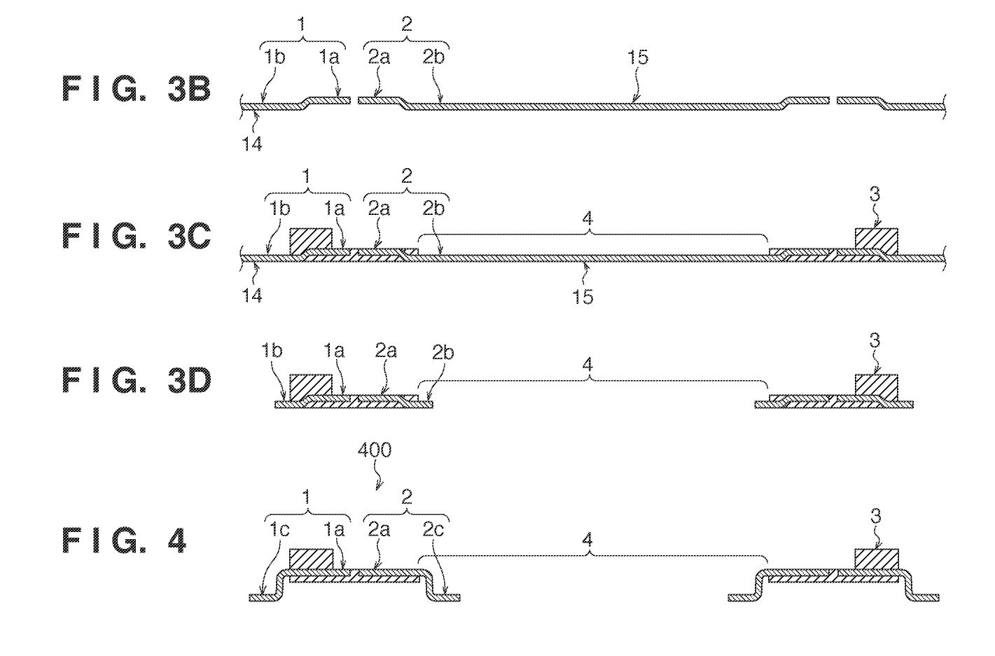

A method for manufacturing the package 100 will now be described with reference to FIGS. 3A to 3D. FIGS. 3B to 3D are B-B′ cross-sectional views of FIG. 3A. A lead frame 300 shown in FIG. 3A is first generated. The lead frame 300 comprises an outer supporting portion 14 and an inner supporting portion 15 inside the outer supporting portion 14. The inner supporting portion 15 is connected and supported by the outer supporting portion 14 through a suspension lead 16. The first leads 1 extend inside from the outer supporting portion 14, and the second leads 2 extend outside from the inner supporting portion 15. The portions inside the first leads 1 are the exposed portions 1a, and the portions outside the first leads 1 are the protrusive portions 1b. The portions outside the second leads 2 are the exposed portions 2a, and the portions inside the second leads 2 are the protrusive portions 2b. The lead frame 300 is formed using a known method, such as a punching process using a mold and a wet etching process.

As shown in FIG. 3B, a bending process for forming steps on the first lead 1 and the second lead 2 is executed. The first lead 1 is bent between the exposed portion 1a and the protrusive portion 1b. The second lead 2 is bent between the exposed portion 2a and the protrusive portion 2b. The extent of the bend and the step is appropriately selected. For example, if the step is large, the space below the semiconductor chip can be large when the semiconductor chip is mounted on. A large space allows installation of a larger heat radiating component.

As shown in FIG. 3C, the frame member 3 including the aperture 4 and a concave shape is formed on the lead frame 300. The frame member 3 is formed so that an outer portion of the first lead 1 is exposed outside the frame member 3, and an inner portion of the second lead 2 is exposed to the aperture 4. An example of the method of processing the frame member 3 includes resin molding using a mold, such as transfer molding and injection molding. A known resin, such as a thermoset resin and a thermoplastic resin, can be used as a material of the frame member 3.

Lastly, as shown in FIG. 3D, the outer supporting portion 14 is separated from the first lead 1, and the inner supporting portion 15 is separated from the second lead 2. Furthermore, the frame part connecting the first leads 1 is cut, and the frame part connecting the second leads 2 is cut. As a result, the protrusive portions 1b and 2b are formed. The length of the protrusive portions 1b and 2b can be, for example, 0.3 mm to 0.5 mm.

As described, according to the present embodiment, a technique for realizing an increase in the number of terminals and an improvement in reliability of the solder joint is provided.

An exemplary package 400 of another embodiment will now be described with reference to FIG. 4. FIG. 4 shows a cross-sectional view of the package 400. A plan view of the package 400 is the same as the plan view of the package 100 shown in FIG. 1A, and the description will not be repeated. Shapes of protrusive portions 1c and 2c of the package 400 are different from the package 100 shown in FIG. 1A. A bending process is applied to the protrusive portions 1c and 2c in the package 400, and the protrusive portions 1c and 2c have gull-wing shapes. More specifically, as seen from the frame member 3, the protrusive portions 1c and 2c extend far in the horizontal direction, folded once, extend in a lower direction of the frame member 3, folded once more, and extend far in the horizontal direction. The shape of the bending process is not limited to the gull-wing shape, as long as the protrusive portions 1c and 2c are bent so that the tips of the protrusive portions 1c and 2c are located lower than the lower side of the frame member 3.

Based on the shape, the space on the lower side of the aperture 4 can be further enlarged compared to the package 100 shown in FIG. 1. Therefore, a larger heat radiating component than that in the package 100 can be arranged between the semiconductor chip and the mounting board, and a semiconductor chip requiring more heat radiation performance can be mounted. The solder can also be wet and spread around the protrusive portions 1c and 2c in the package 400, and a highly reliable solder joint is possible.

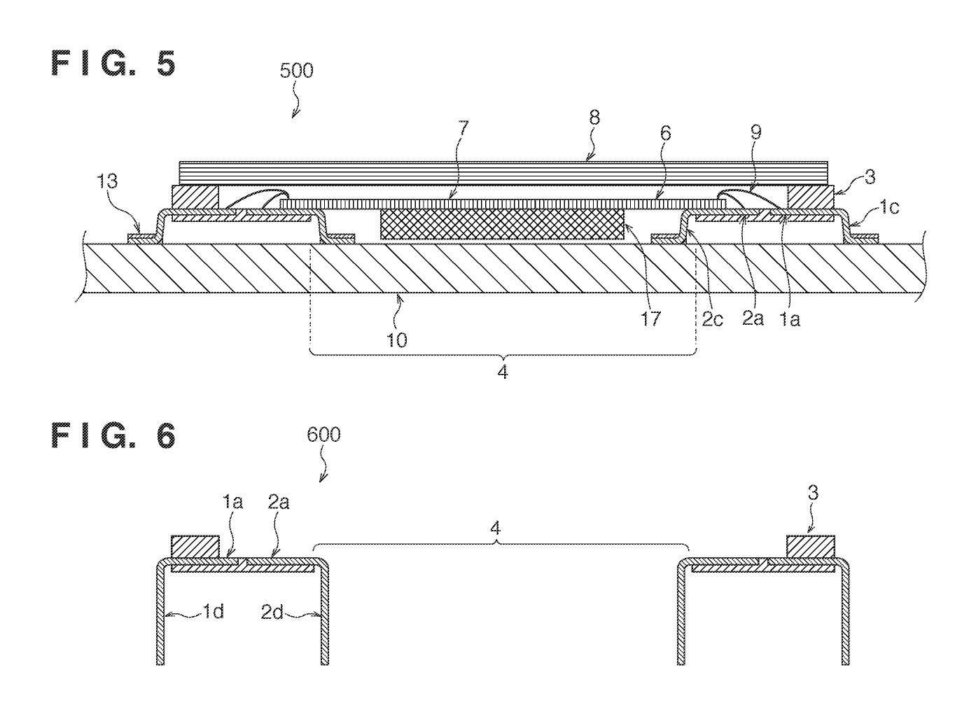

An exemplary semiconductor device in which a semiconductor chip is mounted on the package 400 will now be described with reference to FIG. 5. The present embodiment illustrates an example of a solid-state image sensor 500 using the solid-state image sensing element chip 6 as a semiconductor chip. FIG. 5 is a cross-sectional view of the solid-state image sensor 500 mounted on the mounting board 10. Similar to FIG. 2A, the solid-state image sensing element chip 6 is mounted on the package 400 so as to cover the aperture 4. The bonding wire 9 connects the solid-state image sensing element chip 6 and the exposed portions 1a and 2a. The transparent member 8 is further bonded on the frame member 3, and the solid-state image sensing element chip 6 and the bonding wire 9 are hermetically sealed. The tips of the protrusive portions 1c and 2c are soldered to the mounting board 10 by the solder 13.

The solid-state image sensor 500 comprises a heat radiating component 17 in the space below the solid-state image sensing element chip 6. The heat radiating component 17 is, for example, a tabular or fin-shaped metal plate. The protrusive portions 1c and 2c have gull-wing shapes, and as shown in FIG. 5, the heat radiating component 17 fits between the solid-state image sensing element chip 6 and the mounting board 10. The heat radiating component 17 can be directly bonded to the backside of the solid-state image sensing element chip 6, and the heat generated by the solid-state image sensing element chip 6 can be efficiently radiated. The heat radiation performance further improves if wiring for heat radiation is installed on the mounting board 10.

Instead of the bending process shown in FIG. 3B in the method for manufacturing the package 100, a bending process of the protrusive portions 1c and 2c is executed in the method for manufacturing the package 400. The bending process forms the gull-wing protrusive portions 1c and 2c.

As described, according to the present embodiment, a technique for realizing an increase in the number of terminals and an improvement in reliability of the solder joint is provided. Furthermore, according to the present embodiment, the heat radiation performance can be improved.

An exemplary package 600 of another present embodiment will now be described with reference to FIG. 6. FIG. 6 shows a cross-sectional view of the package 600. A plan view of the package 600 is the same as the plan view of the package 100 shown in FIG. 1A, and the description will not be repeated. Shapes of protrusive portions 1d and 2d of the package 600 are different from the package 100. A bending process is applied to the protrusive portions 1d and 2d in the package 400, and as with a DIP type and a SIP type, tips of the protrusive portions 1d and 2d face in a direction perpendicular to the mounted semiconductor chip.

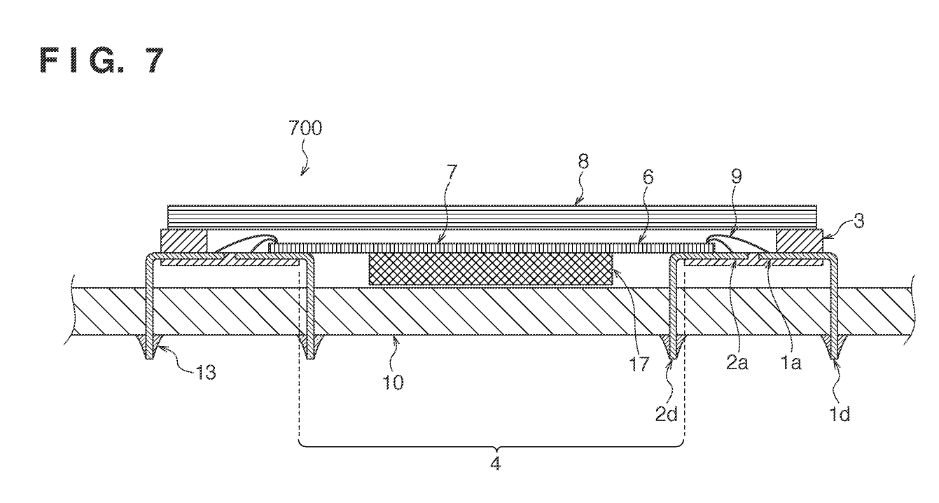

An exemplary semiconductor device with a semiconductor chip mounted on the package 600 will now be described with reference to FIG. 7. The present embodiment illustrates an example of a solid-state image sensor 700 using the solid-state image sensing element chip 6 as a semiconductor chip. FIG. 7 is a cross-sectional view of the solid-state image sensor 700 mounted on the mounting board 10. The same parts as the solid-state image sensor 500 shown in FIG. 5 will not be described. The protrusive portions 1d and 2d are perpendicularly inserted to the mounting board 10 and soldered on the backside of the mounting board 10. Therefore, as compared to the surface mounting, a more reliable solder joint can be obtained with respect to the warpage or deformation of the mounting board 10. The interval between the lower side of the package 600 and the mounting board 10 can be freely adjusted based on the length of the protrusive portions 1d and 2d and the extent of insertion to the mounting board 10. This increases the degree of freedom of the shapes, sizes, etc. of components, such as the heat radiating component 17 arranged in the space on the lower side of the package 600.

The method for manufacturing the package 600 is the same as the method for manufacturing the package 400, and the description will not be repeated.

As described, according to the present embodiment, a technique for realizing an increase in the number of terminals and an improvement in reliability of the solder joint is provided. Furthermore, according to the present embodiment, the heat radiation performance can be improved.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-242784, filed Oct. 21, 2009, which is hereby incorporated by reference herein in its entirety.

What is claimed is:

1. A package for mounting a semiconductor chip, the package comprising:
a frame member including an aperture;
a first lead including a portion connectable to the semiconductor chip and a portion projecting outside from an outer sidewall of the frame member; and
a second lead including a portion connectable to the semiconductor chip and a portion projecting inside the aperture from an inner sidewall of the frame member.

2. The package according to claim 1, wherein
the projecting portion of the first lead and the projecting portion of the second lead are bent so that a tip of the projecting portion of the first lead and a tip of the projecting portion of the second lead are positioned lower than a lower side of the frame member.

3. The package according to claim 1, wherein
the projecting portion of the first lead and the projecting portion of the second lead are bent so that the tip of the projecting portion of the first lead and the tip of the projecting portion of the second lead face a direction perpendicular to a surface of the semiconductor chip.

4. A semiconductor device comprising:
the package according to claim 1; and
a semiconductor chip that is arranged at a position covering the aperture of the package and that is connected to the connectable portion of the first lead and the connectable portion of the second lead.

5. A method for manufacturing a package for mounting a semiconductor chip, the method comprising:
forming a lead frame including a first lead extending inside from an outer supporting portion and a second lead extending outside from an inner supporting portion positioned inside the outer supporting portion;
forming, on the lead frame, a frame member including an aperture so that an outer portion of the first lead is exposed outside the frame member and an inner portion of the second lead is exposed to the aperture; and
separating the outer supporting portion from the first lead and the inner supporting portion from the second lead.
